(19) United States
(12) Patent Application Publication
(10) Pub. No.: US 2003/0223516 A1
(43) Pub. Date: Dec. 4, 2003

(54) Sequential bezout space-time equalizers for MIMO systems

(76) Inventors: Xinying Zhang, Princeton, NJ (US); Sun Yuan Kung, Princeton, NJ (US); Jinyun Zhang, New Providence, NJ (US); Giovanni Vannucci, Red Bank, NJ (US)

Correspondence Address: MITSUBISHI ELECTRIC INFORMATION, TECHNOLOGY CENTER AMERICA, 8TH FLOOR, 201 BROADWAY, CAMBRIDGE, MA, 02139

(21) Appl. No.: 10/156,366

(22) Filed: May 28, 2002

(51) Int. Cl. H03D 1/04

(52) U.S. Cl. 375/346

(57) ABSTRACT

A receiver in a multiple-input-multiple-output, frequency-selective fading wireless communication systems sequentially recovers multiple data stream. A next input stream, having a highest signal-to-noise ratio is selected. The selected input stream is equalized, detected and decoded. The decoded data stream is then substracted from the data streams, and the selecting, equalizing, detecting and decoding, and subtracting is repeated until all of the data streams have been decoded.

### FIELD OF INVENTION

The present invention relates generally to communications systems, and more particularly to interference cancellation and signal recovery in wireless multiple-input-multiple-output communications systems.

### BACKGROUND OF THE INVENTION

Multiple-input-multiple-output (MIMO) systems have the potential to greatly increase the capacity of wireless communications systems where there are multiple antennas in both the transmitter and the receiver.

A MIMO system has p transmitters and q receivers. If sⱼ(k) is a coded input sequence at transmitters j=1, . . . , p, hᵢⱼ(k) is a channel impulse response from transmitter j to receiver i=1, . . . , q, and d is a maximum length of the channel impulse response among all of the channels, then an output xᵢ(k) at receiver i can be expressed as a convolutional product

$${x}_{i} ( k ) = {\sum }_{j = 1}^{p} {\sum }_{l = 0}^{d} {h}_{ij} ( l ) {s}_{j} ( k - l ) + {n}_{i} ( k ) \qquad ( 1 )$$

where nᵢ(k) denotes additive-white-Gaussian-noise (AWGN) at the receiver i.

An equivalent expression of equation (1) in the frequency domain is

x(D)=H(D)s(D)+n(D) (2)

where s(D)=[s₁(D) s₂(D) . . . sₚ(D)]^{T}, x(D)=[x₁(D) x₂(D) . . . x_{q}(D)]^{T}, H(D)={H₁ⱼ(D)}_{1,j}, and n(D)=[n₁(D) n₂(D) . . . n_{q}(D)]^{T} are the z-transform vectors (or matrix), and D=z⁻¹ denotes a unit delay of corresponding sequences or impulse responses.

The q×p polynomial matrix H(D) is referred to as the transfer function of the MIMO system, and the polynomial vector hⱼ(D)=[h₁ⱼ(D) h₂ⱼ(D) . . . h_{qj}(D)]^{T} (j=1, . . . p) is the channel response from j^{th} transmitter antenna to all receive antennas.

In such a wireless system, transmitted signal sequences are subject to time-domain inter-symbol interference (ISI) and space-domain inter-channel-interference (ICI) from other signals. This makes it difficult to correctly retrieve the transmitted sequences. In addition, for most practical channels, the frequency-response characteristics are time-variant. This makes it more difficult to design an optimum filter and demodulator.

A Bezout equalizer offers an effective tool to reduce ISI and ICI in MIMO systems. The Bezout equalizer uses an array of linear finite-impulse response (FIR) filters. To retrieve the input sequences

$${\{ {s}_{j} ( k ) \}}_{j = 1}^{p}$$

from noise-corrupted observations

$${\{ {x}_{i} ( k ) \}}_{i = 1}^{q} ,$$

the FIR filter can be applied at the receiver, see Ding et al., “Blind Equalization and Identification,” Marcel Dekker, Inc., New York, 2001. With appropriate parameters, a linear combination of the q filtered receiver streams can reconstruct an individual input stream while reducing both ISI and ICI.

The following definitions are used for the Bezout inverse theory, set out below.

Definition 1—Perfect Recoverability

Given a MIMO channel with transfer function H(D), the j^{th} input is perfectly recoverable (PR) of order ρ if and only if there exist a nonnegative integer kⱼ and a 1×q polynomial vector g(D) with deg g(D)<ρ such that

$$g ( D ) H ( D ) = {D}^{{k}_{j}} {e}_{j} \qquad ( 3 )$$

where eⱼ is a unit (row) vector with all elements zero except 1 at position j. The FIR filter array corresponding to g(D) in equation (3) is referred to as a (j, ρ, k) Bezout equalizer. The MIMO system is said to be PR if and only if all the p inputs are PR of a finite order.

An expresion

$$g ( D ) \times ( D ) = {s}_{j} ( D ) {D}^{{k}_{j}}$$

+noise term is obtained when g(D) in equation (3) is applied on the receiver data yields, i.e. sⱼ(k) is reconstructed with noise and delay kⱼ. It is known that the condition of PR for a MIMO system hinges upon the notion of coprimeness of the transfer function H(D), see Kailath et al., “Linear Systems,” Prentice-Hall, Englewood Cli., NJ, 1980, and Kung et al., “An Associative Memory Approach to Blind Signal Recovery for SIMO/MIMO Systems,” IEEE Workshop on Neural Network for Signal Processing, September 2001.

Definition 2—Coprime Polynomial Matrices

A p×p polynomial matrix R(D) is said to be a right common divisor of the rows in H(D) if H(D)=H′(D)R(D), where H′(D) is itself a polynomial matrix. Furthermore, R(D) is called a greatest right common divisor (grcd) if for any other right common divisor R′(D) there exists a polynomial matrix C(D) such that R(D)=C(D)R′(D). A polynomial matrix is delay-permissive right coprime if the determinant of its grcd has the form of a pure delay:

$$det R ( D ) = {D}^{{k}_{0}} .$$

Theorem 1—PR Condition of MIMO System

A p-in-q-out MIMO system with transfer function H(D) is PR if and only if H(D) is delay-permissive right coprime.

It is assumed that the channel transfer function is available at the receiver end via some estimation procedure. For perfect recovery in general, the coprime condition in Theorem 1 requires more receivers than transmitters, i.e., q>p.

FIG. 1 shows a prior art parallel architecture of a MIMO system 100. The system 100 includes transmitters 110, MIMO channel 120 subject to noise 130, receivers 140, and Bezout equalizers 200. Here, sⱼ(k) 111 are the inputs at the transmitters 110, xᵢ(k) 141 are the outputs at the receivers 140, and ŝⱼ(k) 201 are the recovered inputs after equalization 200. Under PR condition

$$G ( D ) H ( D ) = Diag \{ {D}^{{k}_{j}} \} .$$

FIG. 2 shows the prior art Bezout equalizer 200 with FIRs 210. The design of the Bezout equalizer can be decoupled into a task of separately designing individual equalizers for each input.

One prior art technique, which theoretically achieves channel capacity in flat-fading MIMO systems, is called BLAST, see Foschini, “Layered Space-time Architecture for Wireless Communication in Fading Environments When Using Multiple Antennas,” Bell Labs Technical Journal, Vol. 1, pp.41-59, Autumn 1996. BLAST recognizes that flat-fading MIMO channels, i.e., channels with multiple transmit and receive antennas, have enormous capacity. Capacity grows linearly with the number of transmit antennas as long as the number of receiving antennas is greater than the number of transmitting antennas. The original BLAST used a cyclic association of data streams, called layers, with transmit antennas, thereby producing an “averaged” channel which is the same for all layers. Difficulties in the realization of the original BLAST led to a modified architecture where each layer is associated with a certain transmit antenna.

However, in order to achieve the full capacity of the MIMO channel, long data blocks, powerful channel coding, and perfect detection of each layer are required. In addition, in practical systems, the problem of error propagation limits the performance. Particularly, the overall diversity level is limited by the diversity level obtained in the layer which is detected first. Most important, BLAST is only valid for flat-fading channels, which limits its applicability to frequency-selective channels in broadband communication.

Therefore, there is a need for a receiver in MIMO systems that improve upon the prior art.

### SUMMARY OF THE INVENTION

The invention provides a system and method that combines Bezout space-time equalizers with sequential detection and decoding techniques for multiple-input-multiple-output (MIMO) communications systems. With a sequential space-time equalizer, previously detected transmitting streams are used to reduce interference in subsequent detected input stream. The sequential equalization and detection/decoding according to the invention successively reduces the number of unknown input streams of the MIMO system. Excess dimensionality offered by the increasing asymmetry between the transmitted and received signal spaces provides the necessary flexibility that improves the capacity of the system.

More particularly, the invention provides a method and system for equalizing signals transmitted over a multi-path channel and canceling the interference from the data streams sequentially. An input data stream with a highest post-processing signal-to-noise ratio (SNR) is recovered first. The interference generated by this stream is then cancelled before detecting the stream with the next highest SNR. This procedure is recursively executed until all the data streams have been recovered.

Furthermore, the invention provides a system and method that processes the input sequences via a layered and pipeline architecture.

In the system and method according to the invention, two additional parameters are used: equalizer order and equalization delay. By selecting appropriate equalizer order and equalization delay parameters, the overall performance of the system can be optimized.

### BRIEF DESCRIPTION OF THE DRAWINGS

FIG. 1 is a block diagram of a prior art parallel architecture of a MIMO system;

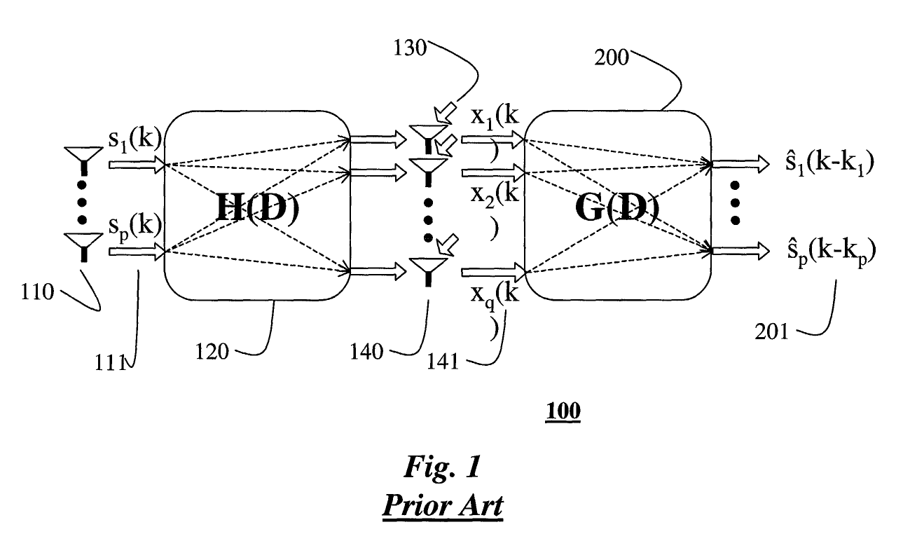

FIG. 2 is a block diagram of a prior art Bezout equalizer;

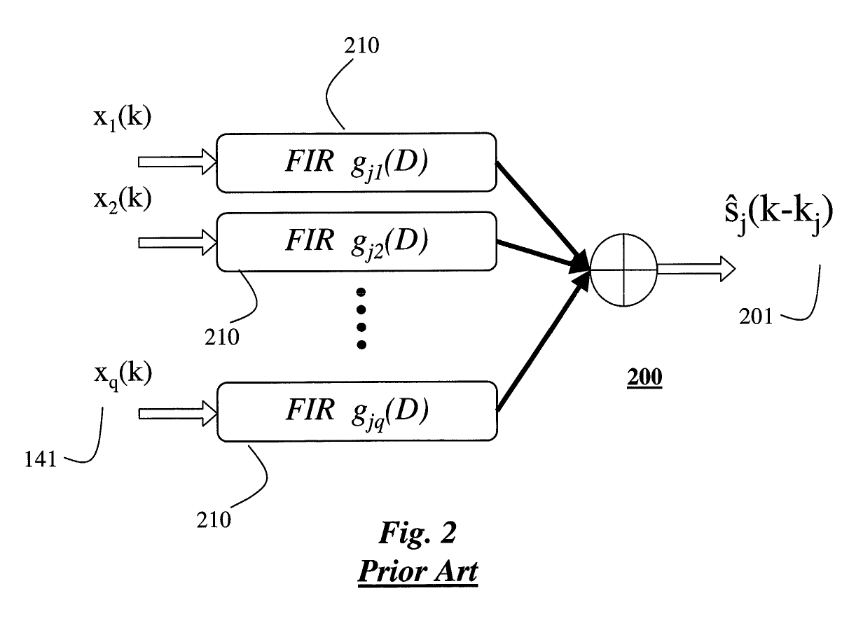

FIG. 3 is a block diagram of a receiver according to the invention;

FIG. 4 is a block diagram of sequential equalization, detection/decoding and cancellation according to the invention;

FIG. 5 is a block block diagram of a pipelined sequential Bezout equalizer according to the invention; and

FIG. 6 is a block diagram of a layered pipeline sequential Bezout equalizer according to the invention.

### DETAILED DESCRIPTION OF THE PREFERRED EMBODIMENT OF THE INVENTION

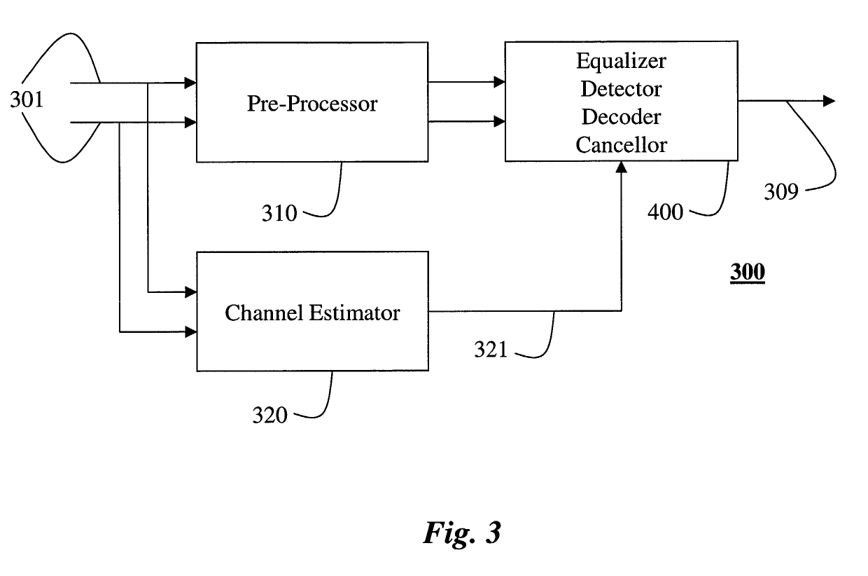

FIG. 3 shows components of a receiver 300 in a MIMO system that uses the invention. The components include a pre-processor 310, a channel estimator 320, and a sequential Bezout equalizer, detector/decoder, and interference canceller 400. The receiver 100 takes as input 301 signals received at multiple antennas, and produces as output 309 decoded data streams.

The operation of the receiver 300 is as follows. During the pre-processing 310, the input signals are filtered and time synchronized to produce data streams for the Bezout Space-Time Equalizer. Channel impulse response estimation is performed in block 320 to provide the H(D) 321 to the Bezout space-time equalizer 400. The functions of block 400 are described in greater detail below.

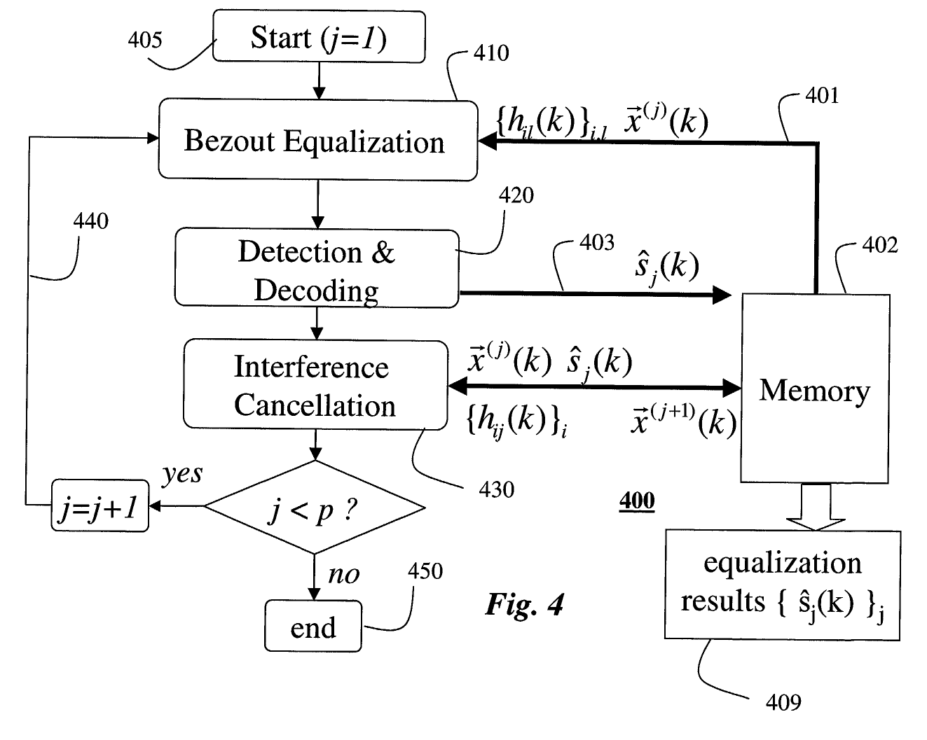

FIG. 4 shows sequential equalization, detection/decoding and cancellation 400 according to the invention. This method yields a better SNR or capacity in a MIMO system than obtainable with prior art techniques.

First, select 405 a next input stream, of the j=1, . . . , p data streams 401 stored in a memory 402, that has a highest post-processing signal-to-noise ratio (SNR). Then, equalize 410 the selected data stream with the Bezout FIR filter, the signal is then detected and decoded 420 using an error-correction decoder. Next, cancel 430 the contribution of the detected stream 403 from the received data stored in the memory 402 via a successive interference cancellation strategy as is commonly known in signal processing. In essence, the cancellation 430 can be performed by subtracting the decoded signal from the received signal.

Repeat 440 the above steps of equalizing, detecting/decoding, and cancellation for a next input stream using the interference-reduced received signal 401, until all streams {sⱼ(k)}ⱼ 409 have been detected 450. Such a recursive method leads to a sequential Bezout equalization strategy according to the invention.

Initially, we set H⁽¹⁾(D)=H(D), x⁽¹⁾(D)=x(D) and k₀=0. At step j, (j−1) input streams from transmitters have already been equalized, detected/decoded, and their interferences have been cancelled (subtracted) 430 from the receiver observation x(D) to obtain a new data vector, denoted as x^{(j)}(D). The operations in the j^{th} recursive step are then: design an individual Bezout equalizer for stream j so that

$${g}_{j} ( D ) {H}^{( j )} ( D ) = {D}^{{k}_{j}} [ 1 \; 0 … 0 ] \qquad ( 4 )$$

and apply the equalizer on the recursively updated received data x^{(j)}(D) 401:

$$\begin{matrix}{y}_{i} ( D ) = {g}_{j} ( D ) {x}^{( j )} ( D ) \\ = {D}^{{k}_{1} + {k}_{2} + … + {k}_{j}} {s}_{j} ( D ) + noise term\end{matrix} \qquad ( 5 )$$

Then, detect and decode the j^{th} selected stream with error-correcting decoding 420 on yⱼ(D). Provided the coding scheme has sufficient error-correction ability, we obtain a correct reconstruction of the input sequence: ŝⱼ(D)=sⱼ(D), with delay

$${\sum }_{i = 1}^{j} {k}_{j} .$$

Cancel 430 the ICI generated by j^{th} input stream from the received observation vector based on the following recursive formula which basically is a subtraction:

x^{(j+1)}(D)=D^{k}^{ⱼ}x^{(j)}(D)−D^{k}^{₁}^{+ . . . +k}^{ⱼ}hⱼ(D)ŝⱼ(D) (6)

Equation (6) represents a virtually truncated MIMO system x^{(j+1)}(D)=D^{k}^{₁}^{+ . . . +}^{ⱼ}H^{(j+1)}(D)s^{(j+1)}(D) with

H^{(j+1)}(D)=[hⱼ₊₁(D) . . . hₚ(D)]

s^{(j+1)}(D)=[sⱼ₊₁(D) . . . sₚ(D)]^{T} (7)

The reduced transfer function H^{(j+1)}(D) is the last (p−j) columns of H(D).

This procedure is recursively applied 440 until all the p input sequences are decoded at the end 450. Each recursion results in a size-reduced MIMO system with one less input.

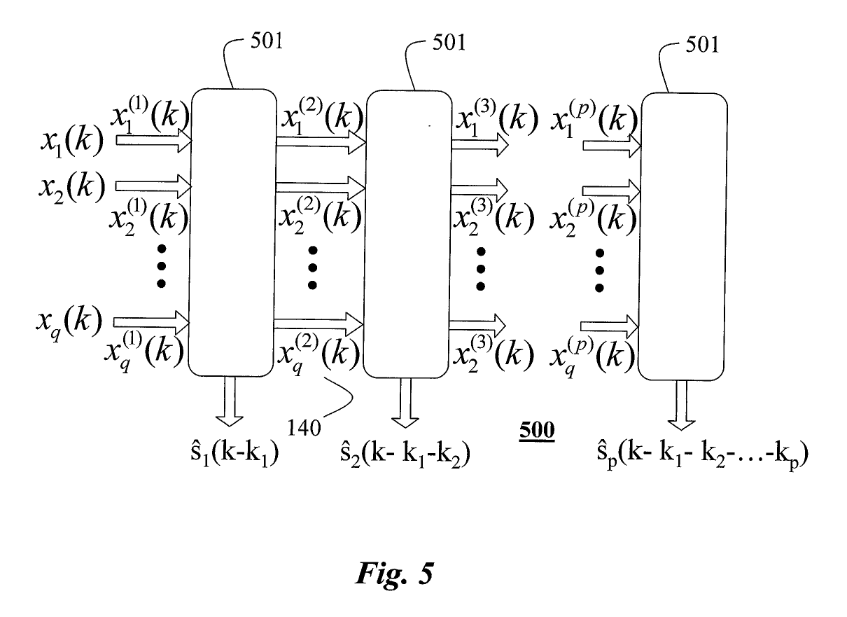

FIG. 5 shows a pipelined implementation 500 for realization of the sequential Bezout equalizer 400 according to the invention. There are p layers 501 in the pipeline 500 for recovering p data streams. Each layer 501 includes the steps of equalization 410, detecting and decoding 420, and interference cancellation 430.

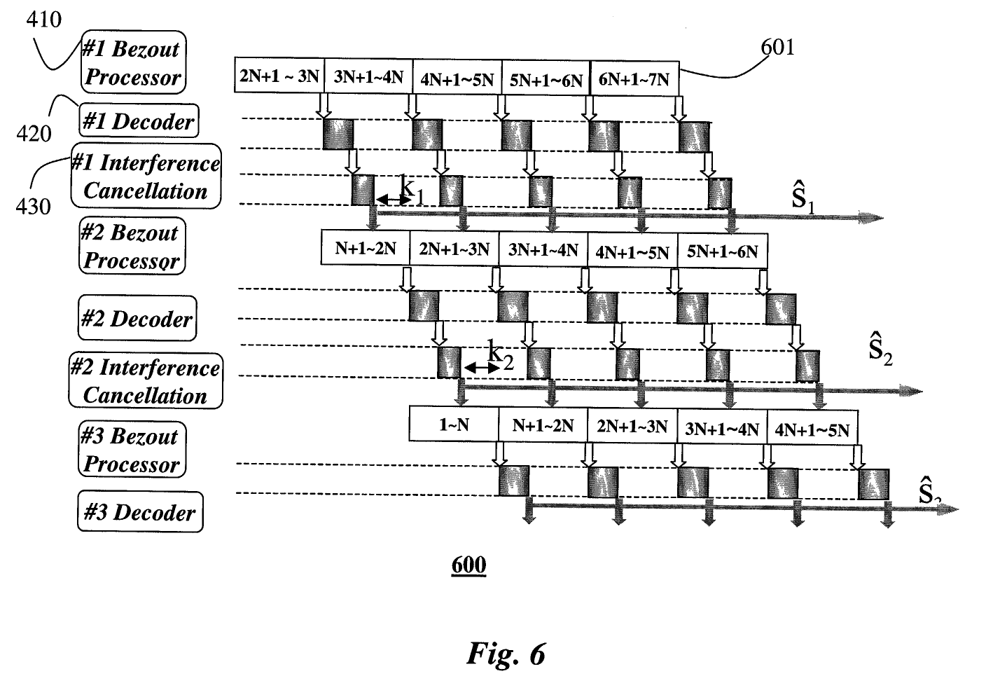

The layered and pipelined architecture 600 is shown in FIG. 6. The processing steps in each stage proceed from left to right. In the first stage, an individual input sequence is equalized 410 sequentially one block after the other with the temporal range of detected input symbols denoted by the labels on the blocks, e.g., N+1˜2N. Each equalized block is then forwarded to the detector/decoder stage 420. Finally, the error-corrected sequence is used by the interference canceller (IC) stage 430 to cancel the interference contributed by the detected sequence(s) from the receiver data. The interference-reduced data are now ready to be processed in the next stage, as indicated by the down arrows.

Each pipeline stage incurs an equalization delay of kⱼ for j=1, . . . , p together with a processing delay generated by the decoder and IC stages. The overall effect of these delays is depicted by the inter-layer block shifts with respect to processing time.

For two blocks with the same labeling, i.e., data blocks of two input streams within the same time interval, the block associated with the lower stage is processed later time. In particular, the equalization delay generated by each individual Bezout equalizer is propagated to the next stage through the decoder and IC stages, as shown by the inter-stage arrows 601. The interference-reduced received data at the bottom of j^{th} layer arrive at the (j+1)^{th} stage in the previous data block, labeled by N+1˜2N, with exactly kⱼ symbols preceding the beginning of the current block, labeled by 2N+1˜3N.

Although the lower (later) stages have a larger processing delay, they have a greater amount of estimated inputs obtained from the higher (earlier) stages. Consequently, assuming no error propagation, a larger amount of interference is cancelled from the received data by the later stages. This, in turn, implies that the later stages are able to deliver a higher SNR gain over the parallel scheme of the prior art.

Optimal Order of Signal Detection

To prevent error propagation in this sequential architecture, it is preferred to first recover the j*^{th} input stream whose individual Bezout equalizer yields a highest post-processing 310 SNR. The detection order in the subsequent stages can then be determined in the same manner.

The following process can be used for determining the order for detecting the input streams.

Initially, set H⁽¹⁾(D)=H(D), and an input j*^{th} stream with a highest SNR after pre-processing 310, see equation (12) below, is selected. Then, remove the j*^{th} column from H⁽¹⁾(D) to form a truncated system H⁽²⁾(D). This corresponds to the cancellation 430 of interference contributed by the j*^{th} input stream from the receiver data. With the truncated transfer function H⁽²⁾(D), and its corresponding individual Bezout equalizer design, the second stream is selected according to the same SNR criterion. This procedure is recursively performed until all of the p data streams 409 have been decoded.

A qρ×p(d+ρ) block Toeplitz resultant matrix is given below:

$${Γ}^{ρ} [ H ] = [ \begin{matrix}{H}_{0} & {H}_{1} & … & {H}_{d} & 0 & … & 0 \\ 0 & {H}_{0} & … & {H}_{d - 1} & {H}_{d} & … & 0 \\ ⋮ & ⋮ & ⋰ & ⋰ & ⋰ & ⋰ & ⋮ \\ 0 & 0 & … & {H}_{0} & {H}_{1} & … & {H}_{d}\end{matrix} ] \qquad ( 8 )$$

where Hᵢ denotes the i^{th} order coefficient matrix of the transfer function H(D), i.e.,

$$H ( D ) = {\sum }_{i = 0}^{d} {H}_{i} {D}^{i} .$$

Due to the presence of the left null-space of H(D), there may exist non-unique (j, ρ, k) Bezout equalizers satisfying equation (3). At the output of any equalizer g(D), the recovered signal preserves the power of the j^{th} transmitting stream.

However, the i.i.d. AWGN in the receiver is filtered by g(D), leading to a post-processing noise power of

$$\frac{{N}_{0}}{2} {‖ {g}^{->} ‖}^{2} ,$$

where N₀ is the noise spectral density and \vec{g}=└g₀ g₁ . . . g_{ρ-1}┘ denotes the 1×qρ coefficient vector of equalizer g(D). In order to maximize the post-processing SNR, one design criterion minimizes the 2-norm of \vec{g}.

According to equation (3), an optimal (j, ρ, k) Bezout equalizer, if it exists, can be equivalently derived in a resultant matrix notation as:

$${{g}^{->}}^{*} = arg {min}_{{g}^{->}} \{ {‖ {g}^{->} ‖}^{2} \vert {g}^{->} {Γ}^{ρ} [ H ] = {{e}^{->}}_{r} \} \qquad ( 9 )$$

where \vec{e}ᵣ is a row vector with all elements zero except 1 at r=j+pkⱼ.

Given the transfer function H(D), equation (9) can be solved by taking a singular value decomposition (SVD) on Γ^{ρ}[H]:

Γ^{ρ}[H]=UΣV (10)

where Σ is a square diagonal matrix of positive singular values. Then, the solution to equation (9) is

\vec{g}*=\vec{e}ᵣV^{H}Σ⁻¹U^{H} (11)

if and only if \vec{e}ᵣε row span(Γ^{ρ[H]).}

Determination of j*. and kⱼ*

Given a predetermined equalizer order, the input stream associated with the first stage can be selected via a joint optimization of ∥\vec{g}*∥² in equation (11) over both the stream index j and the equalization delay kⱼ. As the pair (i, kⱼ) has a one-to-one correspondence with r=j+pkⱼ, see equation (9), the same goal can be achieved by minimizing ∥\vec{g}*∥² over r:

$$\begin{matrix}{r}^{*} = arg {min}_{r} \{ {( {V}^{H} {Σ}^{- 2} V )}_{rr} \vert {{e}^{->}}_{r} ∈ Row Span \{ V \} \} \\ {j}^{*} = [ ( {r}^{*} - 1 ) mod p ] + 1 \\ {k}_{j}^{*} = d + ρ - 1 - \frac{{r}^{*} - {j}^{*}}{p}\end{matrix} \qquad ( 12 )$$

Thus equation (12) provides the optimal order for signal detection. The same equation is used to determine the best recovery stream and equalization delay for every recursion or stage of the pipeline, upon replacement of H(D)in equation (9) and (10) by H^{(l)}(D) and p by p−l+1 in recursion l.

In the receiver according to the invention, each recursion reduces the dimension of the updated transfer function H⁽ⁱ⁾(D) by one. This implies a reduced virtual MIMO channel with one less input stream. Following the same idea as in equation (9), with the layered detection procedure with ordering 1, 2, . . . p, the optimal individual Bezout equalizer to recover input stream j is

$${{g}^{->}}^{*} = arg {min}_{{g}^{->}} \{ {‖ {g}^{->} ‖}^{2} \vert {g}^{->} {Γ}^{ρ} [ {H}^{( j )} ] = {{e}^{->}}_{r} \} \qquad ( 13 )$$

Because H^{(j)}(D) is a size-reduced version of H(D), all the null-space solutions associated with the latter are also valid solutions for the former, but not vice versa. This means the post-processing SNR corresponding to H^{(j)}(D) is equal or superior to H(D). In short, the SNR or capacity associated with the remaining source signals is significantly enhanced.

Effect of the Invention

The receiver with the sequential Bezout equalizers according to the invention has about double the SNR gain as that obtained by a parallel architecture of equal order. In addition, the receiver is less sensitive to variations of equalization delay, which provides more flexibility for recovery. For a fixed equalizer order, the sequential architecture according to the invention has a much wider range with reasonable performance, while the parallel architecture degenerates more noticeably around the optimal delay point.

This invention is described using specific terms and examples. It is to be understood that various other adaptations and modifications may be made within the spirit and scope of the invention. Therefore, it is the object of the appended claims to cover all such variations and modifications as come within the true spirit and scope of the invention.

We claim:

1. A method for receiving a plurality of data streams in a multiple-input-multiple-output wireless communication systems, comprising:
selecting a next input stream of the plurality of data streams;
equalizing the next input stream;
detecting and decoding the equalized input stream;
subtracting the decoded input stream from the plurality of data stream; and
repeating the selecting, equalizing, detecting and decoding, and subtracting until all of the plurality of data streams have been decoded.

2. The method of claim 1 wherein the selected input stream has a highest signal-to-noise ratio.

3. The method of claim 1 wherein the equalizing is performed by a Bezout equalizer.

4. The method of claim 1 further comprising:
error-correcting while detecting and decoding.

5. The method of claim 1 wherein the equalizing, detecting and decoding, and subtracting are pipelined with a plurality of layers.

6. The method of claim 5 wherein there is one layer for each of the plurality of data streams.

7. A receiver for receiving a plurality of data streams in a multiple-input-multiple-output wireless communication systems, comprising:
means for selecting a next input stream of the plurality of data streams;
an equalizer configured to equalize next input stream;
a detector and decoder configured for detecting and decoding the equalized input stream;
means for subtracting the decoded input stream from the plurality of data stream; and
means for repeating the selecting, equalizing, detecting and decoding.

8. The receiver of claim 7 wherein the means for selecting a next input stream, the equalizer, the detector and decoder, and the means for subtracting are pipelined.
